(19) United States
(12) Patent Application Publication
(10) Pub. No.: US 2023/0378105 A1
(43) Pub. Date: Nov. 23, 2023

(54) POWER AMPLIFIER CIRCUIT

(71) Applicant: Murata Manufacturing Co., Ltd., Kyoto (JP)

(72) Inventor: Shohei IMAI, Kyoto (JP)

(21) Appl. No.: 18/366,169

(22) Filed: Aug. 7, 2023

Related U.S. Application Data
(63) Continuation of application No. PCT/JP2022/004579, filed on Feb. 7, 2022.

(30) Foreign Application Priority Data
Feb. 8, 2021 (JP) 2021-018553

(51) Int. Cl. H01L 23/66; H03F 3/24; H03F 1/08; H01L 21/027; H01L 23/00

(52) U.S. Cl. CPC H01L 23/66; H03F 3/245; H03F 1/086; H01L 21/0274; H01L 24/16; H01L 2924/1421; H03F 2200/451; H03F 2200/537; H01L 2223/6616; H01L 2223/6672; H01L 2224/16055; H01L 2224/16146

(57) ABSTRACT

A power amplifier circuit includes a first carrier amplifier and a first peak amplifier. The first carrier amplifier includes a differential amplifier circuit having first and second transistors. The first peak amplifier is formed in or on a semiconductor substrate, which is the same semiconductor substrate in or on which the first carrier amplifier is formed. The emitter or the source of the first transistor is electrically connected to the emitter or the source of the second transistor. The emitter or the source of the first transistor is electrically connected to a ground electrode via a first bump. The emitter or the source of the second transistor is electrically connected to the ground electrode via a second bump. The second bump is different from the first bump.

### CROSS REFERENCE TO RELATED APPLICATION

This is a continuation of International Application No. PCT/JP2022/004579 filed on Feb. 7, 2022 which claims priority from Japanese Patent Application No. 2021-018553 filed on Feb. 8, 2021. The contents of these applications are incorporated herein by reference in their entireties.

### BACKGROUND OF THE DISCLOSURE

### Field of the Disclosure

The present disclosure relates to a power amplifier circuit.

### Description of the Related Art

The Doherty amplifier is a high-efficiency power amplifier. Typically, in the Doherty amplifier, a carrier amplifier and a peak amplifier are connected in parallel with each other. The carrier amplifier operates regardless of the power level of an input signal. When the power level of the input signal is low, the peak amplifier is turned OFF. When the power level of the input signal is high, the peak amplifier is turned ON. When the power level of the input signal is high, the carrier amplifier is operated while maintaining the saturated output power level (see Patent Document 1, for example).
Patent Document 1: Japanese Unexamined Patent Application Publication No. 2011-35754

### BRIEF SUMMARY OF THE DISCLOSURE

In the Doherty amplifier disclosed in Patent Document 1, each of the carrier amplifier and the peak amplifier forms a differential amplifier circuit. The carrier amplifier and the peak amplifier each include two NMOS transistors. The two NMOS transistors are connected to each other at their sources and are electrically connected to a ground electrode using vias or bumps, for example. The differential operation of the carrier amplifier may become insufficient for certain reasons, such as the variations in the characteristics of the transistors and the surrounding environments. In this case, a radio-frequency current flows into the ground electrode by passing through the vias or the bumps which connect the sources of the two NMOS transistors. When a radio-frequency current flows through the vias or the bumps of the carrier amplifier, a magnetic field is produced in proportion to the magnitude of the inductance of the vias or the bumps. This magnetic field induces electromotive force in the vias or the bumps which electrically connect the peak amplifier and the ground electrode with each other. Due to this reason, in the Doherty amplifier disclosed in Patent Document 1, the peak amplifier may fail to operate properly.

To address the above-described issue, it is a possible benefit of the present disclosure to provide a power amplifier circuit which is able to reduce the influence of a magnetic field produced in one amplifier on the other amplifier in a Doherty amplifier.

A power amplifier circuit according to an aspect of the present disclosure includes a first carrier amplifier and a first peak amplifier. The first carrier amplifier includes a differential amplifier circuit having first and second transistors. The first peak amplifier is formed in or on a semiconductor substrate, which is the same semiconductor substrate in or on which the first carrier amplifier is formed. The emitter or the source of the first transistor is electrically connected to the emitter or the source of the second transistor. The emitter or the source of the first transistor is electrically connected to a ground electrode via a first bump. The emitter or the source of the second transistor is electrically connected to the ground electrode via a second bump. The second bump is different from the first bump.

According to the present disclosure, it is possible to provide a power amplifier circuit which is able to reduce the influence of a magnetic field produced in one amplifier on the other amplifier in a Doherty amplifier.

### BRIEF DESCRIPTION OF THE SEVERAL VIEWS OF THE DRAWINGS

FIG. 1 is a schematic diagram illustrating an example of the configuration of a power amplifier circuit according to a first embodiment.

FIG. 2 illustrates an example of an XZ cross section including emitters of output amplifiers.

FIG. 3 illustrates another example of the XZ cross section including the emitters of the output amplifiers.

FIG. 4 illustrates an example of an XY cross section including the emitters of the output amplifiers.

FIG. 5 illustrates another example of the XY cross section including the emitters of the output amplifiers.

FIG. 6 is a schematic diagram illustrating an example of the configuration of a power amplifier circuit according to a second embodiment.

FIG. 7 illustrates an example of an XZ cross section including emitters of output amplifiers according to the second embodiment.

FIG. 8 illustrates an example of an XY cross section including the emitters of the output amplifiers according to the second embodiment.

FIG. 9 illustrates another example of the XY cross section including the emitters of the output amplifiers according to the second embodiment.

FIG. 10 is a schematic diagram illustrating an example of the configuration of a power amplifier circuit according to another embodiment.

FIG. 11 is a schematic diagram illustrating another example of the configuration of the power amplifier circuit according to the embodiment in FIG. 10.

FIG. 12 is a schematic diagram illustrating another example of the configuration of the power amplifier circuit according to the embodiment in FIG. 10.

FIG. 13 illustrates an example of an XZ cross section including emitters of output amplifiers according to a comparative example.

FIG. 14 illustrates another example of the XZ cross section including emitters of output amplifiers according to a comparative example.

### DETAILED DESCRIPTION OF THE DISCLOSURE

### Structure of Power Amplifier Circuit 1000 According to First Embodiment

A power amplifier circuit 1000 is loaded in a mobile phone, for example, and is used for amplifying power of a signal to be transmitted to a base station. The power amplifier circuit 1000 is able to amplify power of signals compliant with communication standards, such as 2G (the second generation mobile communication system), 3G (the third generation mobile communication system), 4G (the fourth generation mobile communication system), 5G (the fifth generation mobile communication system), LTE (Long Term Evolution)-FDD (Frequency Division Duplex), LTE-TDD (Time Division Duplex), LTE-Advanced, LTE-Advanced Pro, and 6G (the sixth generation mobile communication system). The communication standards of signals to be amplified by the power amplifier circuit 1000 are not restricted to the above-described systems. The power amplifier circuit 1000 amplifies an input signal RFin and outputs an output signal RFout. The input signal is a RF (Radio-Frequency) signal and the frequency of the input signal is about several gigahertz to several tens of gigahertz, for example.

The power amplifier circuit 1000 according to a first embodiment includes the Doherty amplifier. The power amplifier circuit 1000 is configured to suppress a magnetic field produced by a radio-frequency signal in a carrier amplifier of the Doherty amplifier. Because of this configuration, the power amplifier circuit 1000 is able to reduce the influence of electromotive force induced in a peak amplifier of the Doherty amplifier caused by the magnetic field produced in the carrier amplifier. As a result, the power amplifier circuit 100 can operate stably as the Doherty amplifier.

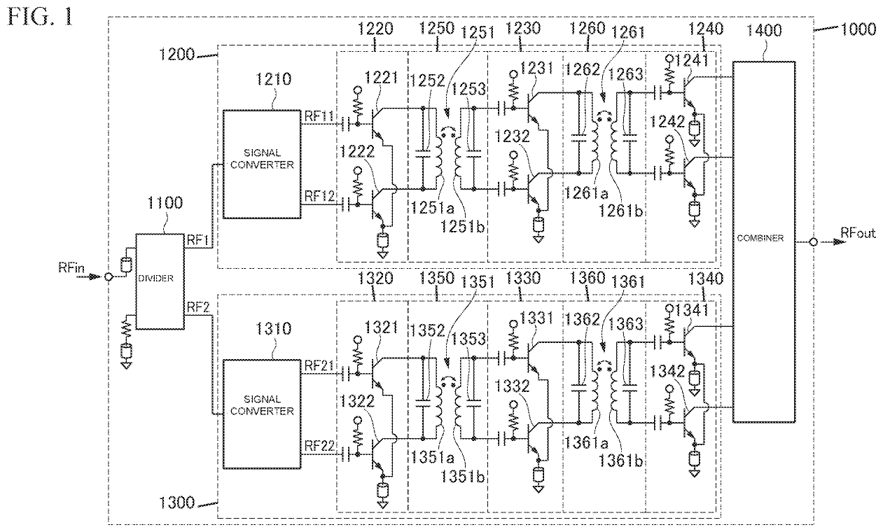

The configuration of the power amplifier circuit 1000 according to the first embodiment will be described below with reference to FIG. 1. FIG. 1 is a schematic diagram illustrating an example of the configuration of the power amplifier circuit 1000 according to the first embodiment. As illustrated in FIG. 1, the power amplifier circuit 1000 is, for example, the Doherty amplifier including a divider 1100, a carrier circuit 1200, a peak circuit 1300, and a combiner 1400.

The divider 1100 divides the input signal RFin into multiple signals, for example. The divider 1100 is a 90-degree hybrid circuit, for example. More specifically, for example, the divider divides the input signal RFin into a signal RF1 to be outputted to the carrier amplifier and a signal RF2 to be outputted to the peak amplifier. The signal RF2 has a phase difference of about 90 degrees from the signal RF1. The divider is not limited to a 90-degree hybrid circuit, and may be a combination of a distributed-element circuit, such as a balun or a coupled-line 3-dB coupler, a Wilkinson power divider, or a Webb power divider and a phase shifter that delays the phase of the input signal RFin by about 90 degrees. “About 90 degrees” includes a range of 45 to 135 degrees, for example.

The carrier circuit 1200 amplifies the input signal RF1 and outputs the amplified signal, for example. The carrier circuit 1200 is biased to class A, AB, or B. That is, regardless of the power level of the input signal, for example, for small instantaneous input power, the carrier circuit 1200 amplifies the input signal RF1 and outputs the amplified signal.

As illustrated in FIG. 1, the carrier circuit 1200 includes a signal converter 1210, a buffer amplifier 1220, a driver amplifier 1230, an output amplifier 1240, and matching circuits 1250 and 1260, for example. In FIG. 1, the carrier circuit 1200 includes the buffer amplifier 1220, the driver amplifier 1230, and the output amplifier 1240. However, the carrier circuit 1200 is not limited to this configuration. For instance, the carrier circuit 1200 may be constituted only by the output amplifier 1240 or may omit the buffer amplifier 1220.

The signal converter 1210 converts the input signal into two signals which are substantially in opposite phase, for example, and outputs the two phases. The signal converter 1210 includes a balun, for example. Hereinafter, for the sake of convenience, it is assumed that the signal converter 1210 receives the signal RF1 and outputs signals RF11 and RF12, which are substantially in opposite phase. In the disclosure, “signals are substantially in opposite phase” means that one signal has a phase difference of 135° to 225° from the other signal.

The buffer amplifier 1220, the driver amplifier 1230, and the output amplifier 1240 each include transistors to be biased by a bias circuit, for example. The transistors are not limited to a particular type. For example, the transistors may be bipolar transistors, such as HBTs (Heterojunction Bipolar Transistors), or field-effect transistors, such as MOSFETs (Metal-oxide-semiconductor Field Effect Transistors). Hereinafter, for the sake of convenience, an explanation will be given, assuming that the transistors are HBTs. If the transistors are FETs, the following configuration can be applied by replacing the emitter by the source in the following description.

The buffer amplifier 1220 includes transistors 1221 and 1222. The signal RF11 is inputted into the base of the transistor 1221. The signal RF12, which is substantially in opposite phase of the signal RF11, is inputted into the base of the transistor 1222.

The driver amplifier 1230 includes transistors 1231 and 1232. The signal generated by amplifying the signal RF11 in the buffer amplifier 1220 is inputted into the base of the transistor 1231. The signal, which is substantially in opposite phase of the signal inputted into the base of the transistor 1231, is inputted into the base of the transistor 1232.

The output amplifier 1240 includes transistors 1241 and 1242. The signal amplified by the driver amplifier 1230 is inputted into the base of the transistor 1241. The signal, which is substantially in opposite phase of the signal inputted into the base of the transistor 1241, is inputted into the base of the transistor 1242. That is, each of the buffer amplifier 1220, the driver amplifier 1230, and the output amplifier 1240 forms a differential amplifier circuit.

The matching circuits 1250 and 1260 are circuits that perform the impedance matching between the buffer amplifier 1220 and the driver amplifier 1230. Hereinafter, an explanation will be given only of the configuration of the matching circuit 1250. The configuration of the matching circuit 1260 is similar to that of the matching circuit 1250 and an explanation thereof will be omitted. The matching circuit 1250 includes a first transformer 1251, and first and second capacitors 1252 and 1253, for example.

The first transformer 1251 is, for example, a wiring transformer including an input winding 1251a and an output winding 1251b. The first transformer 1251 transfers a signal inputted into the input winding 1251a to the output winding 1251b. More specifically, in the first transformer 1251, an amplified signal outputted from the buffer amplifier 1220 is inputted into the input winding 1251a and is outputted from the output winding 1251b. As a result of adjusting the turns ratio of the input winding 1251a to the output winding 1251b, the first transformer 1251 can perform the impedance matching. This makes it possible to perform the impedance matching on a semiconductor substrate 1500 without forming an output matching circuit outside the semiconductor substrate 1500. The power amplifier circuit 1000 can thus be reduced in the circuit scale. A power supply voltage is supplied to, for example, a midpoint g1 of the input winding 1251a. Since the midpoint g1 receives two amplified signals in opposite phase, it can serve as a virtual ground point. This can reduce the noise caused by a power supply circuit. That is, since it is not necessary to provide a choke coil or a bypass capacitor, which is to be used for a power supply source, in the power amplifier circuit 1000, the circuit scale of the power amplifier circuit 1000 is reduced. The first capacitor 1252 is connected in parallel with the input winding 1251a, for example. The second capacitor 1253 is connected in parallel with the output winding 1251b, for example. The first and second capacitors 1252 and 1253 are provided for reducing the influence of the parasitic inductance which may be produced in the first transformer 1251 during the impedance matching of the first transformer 1251. The first capacitor 1252 can be replaced by the parasitic capacitance in the carrier circuit 1200 and may be omitted.

The peak circuit 1300 amplifies the signal RF2 inputted via the divider 1100, for example, and outputs the amplified signal. The peak circuit 1300 is biased to class C, for example. The peak circuit 1300 functions to amplify a signal in a region where the voltage level of the signal RF2 is a predetermined power level or higher, for example. The peak circuit 1300 may be biased to class A, AB, or B, depending on the condition for use.

As illustrated in FIG. 1, the peak circuit 1300 is a differential amplifier circuit, for example, and includes a signal converter 1310, a buffer amplifier 1320, a driver amplifier 1330, an output amplifier 1340, and matching circuits 1350 and 1360. In FIG. 1, the peak circuit 1300 includes the buffer amplifier 1320, the driver amplifier 1330, and the output amplifier 1340. However, the peak circuit 1300 is not limited to this configuration. For example, the peak circuit 1300 may be constituted only by the output amplifier 1340 or may omit the buffer amplifier 1320. For example, the configurations of the signal converter 1310, buffer amplifier 1320, driver amplifier 1330, output amplifier 1340, and matching circuits 1350 and 1360 are similar to those of the signal converter 1210, buffer amplifier 1220, driver amplifier 1230, output amplifier 1240, and matching circuits 1250 and 1260, respectively, and an explanation thereof will thus be omitted.

The combiner 1400 combines the signal RF11 outputted from the carrier circuit 1200 and an amplified signal RF21 outputted from the peak circuit 1300 and outputs the resulting output signal RFout, for example.

### <<Configuration of Output Amplifiers 1240 and 1340>>

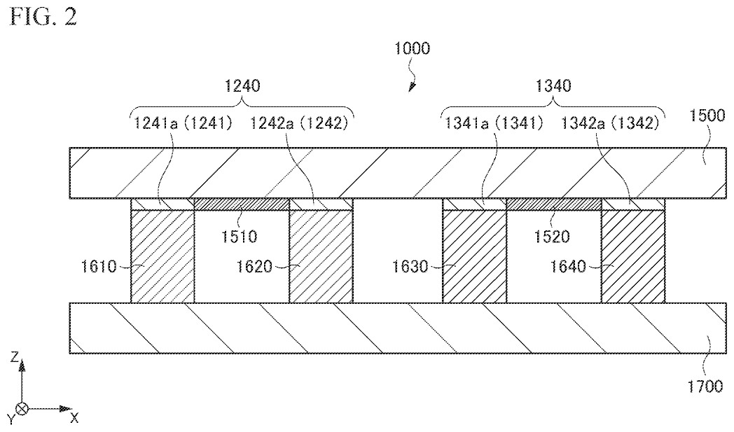

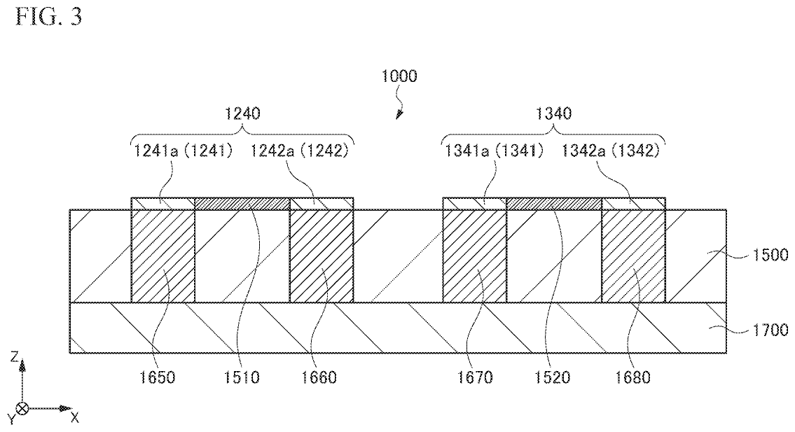

The configuration of the output amplifier 1240 of the carrier circuit 1200 and that of the output amplifier 1340 of the peak circuit 1300 will now be discussed below in detail with reference to FIGS. 2 and 3. FIG. 2 illustrates an example of an XZ cross section including emitters 1241a and 1242a of the output amplifier 1240 and emitters 1341a and 1342a of the output amplifier 1340. FIG. 3 illustrates another example of the XZ cross section including the emitters 1241a and 1242a of the output amplifier 1240 and the emitters 1341a and 1342a of the output amplifier 1340. In FIGS. 2 and 3, the X axis, Y axis, and Z axis are defined as follows, for example. The X axis is an axis extending along one direction of the main surfaces of the semiconductor substrate 1500. The Y axis is an axis extending along another direction of the main surfaces of the semiconductor substrate 1500 and being perpendicular to the X axis. The Z axis is an axis extending along a direction perpendicular to the X axis and the Y axis.

As illustrated in FIG. 2, the output amplifiers 1240 and 1340 are formed in or on the same semiconductor substrate 1500. The emitter 1241a of the transistor 1241 of the output amplifier 1240 is electrically connected to a ground electrode 1700 via a bump 1610, for example. The emitter 1242a of the transistor 1242 of the output amplifier 1240 is electrically connected to the ground electrode 1700 via a bump 1620, for example. The emitter 1241a is electrically connected to the emitter 1242a via a conductive member 1510. The emitter 1341a of the transistor 1341 of the output amplifier 1340 is electrically connected to the ground electrode 1700 via a bump 1630, for example.

The emitter 1342a of the transistor 1342 is electrically connected to the ground electrode 1700 via a bump 1640, for example. The emitter 1341a is electrically connected to the emitter 1342a via a conductive member 1520. As described above, the emitters 1241a, 1242a, 1341a, and 1342a are electrically connected to the ground electrode 1700 via the bumps 1610, 1620, 1630, and 1640, respectively. However, the output amplifiers 1240 and 1340 are not restricted to this configuration. As shown in FIG. 3, the emitters 1241a, 1242a, 1341a, and 1342a may be electrically connected to the ground electrode 1700 using vias 1650, 1660, 1670, and 1680, respectively. Examples of the material forming the bumps and the vias are copper, aluminum, gold, and a carbon-based material (such as a graphite sheet).

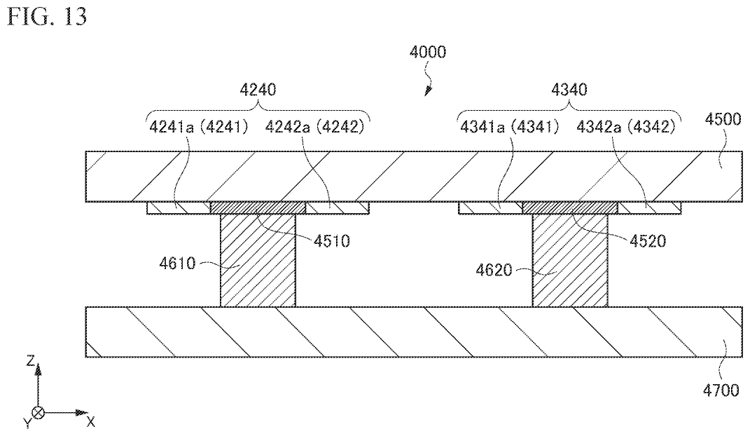

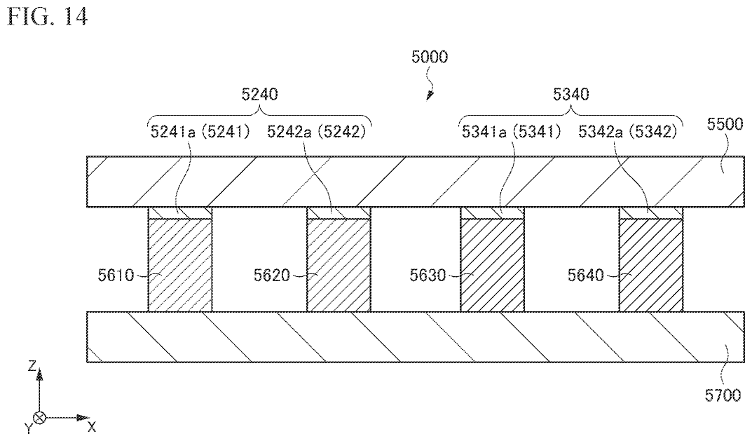

The effectiveness of the power amplifier circuit 1000 of the first embodiment over power amplifier circuits 4000 and 5000 according to comparative examples will be explained below by referring to the configurations of the output amplifiers of the power amplifier circuits 4000 and 5000 with reference to FIGS. 13 and 14. FIG. 13 illustrates an example of an XZ cross section including emitters 4241a and 4242a of an output amplifier 4240 and emitters 4341a and 4342a of an output amplifier 4340 according to a comparative example. FIG. 14 illustrates another example of the XZ cross section including emitters 5241a and 5242a of an output amplifier 5240 and emitters 5341a and 5342a of an output amplifier 5340. An explanation of the elements of the output amplifiers 4240 and 4340 and the elements of the output amplifiers 5240 and 5340 configured similarly to the counterparts of the output amplifiers 1240 and 1340 shown in FIGS. 2 and 3 will be omitted. The definitions of the X axis, Y axis, and Z axis in FIGS. 13 and 14 are similar to those of the X axis, Y axis, and Z axis shown in FIGS. 2 and 3.

As shown in FIG. 13, in the power amplifier circuit 4000, a conductive member 4510 which electrically connects the emitters 4241a and 4242a with each other is electrically connected to a ground electrode 4700 via a bump 4610. A conductive member 4520 which electrically connects the emitters 4341a and 4342a with each other is electrically connected to the ground electrode 4700 via a bump 4620. In the power amplifier circuit 4000, if a radio-frequency current flowing through the transistor 4241 and that through the transistor 4242 do not cancel out each other, a radio-frequency current flows through the bump 4610. In this case, a magnetic field is produced around the bump 4610 due to the radio-frequency current flowing through the bump 4610. Electromotive force is thus induced in the bump 4620 due to the magnetic field produced in the bump 4610. This fluctuates the operation of the peak circuit, thereby making the operation of the power amplifier circuit 4000 unstable.

Additionally, a magnetic field produced in the bump 4620 influences a bump (not shown) of the driver amplifier of the peak circuit. Electromotive force is then induced in the bump of this driver amplifier due to the magnetic field produced in the bump 4620. The magnitude of a radio-frequency current flowing through the driver amplifier is a few or several percent of that of the radio-frequency current flowing through the output amplifier. That is, if the current generated in the transistors of the driver amplifier caused by the electromotive force induced under the influence of the magnetic field is amplified by the driver amplifier, a high current is outputted from the output amplifier of the peak circuit. This makes the operation of the power amplifier circuit 4000 as the Doherty amplifier significantly unstable. More specifically, in the power amplifier circuit 4000, for example, the differential properties of the peak circuit (the capability of the peak circuit to make signals opposite in phase with the same amplitude) are degraded and the gain and the phase of the output amplifier and the driver amplifier of the peak circuit are varied. This leads to a failure to efficiently combine output the power of the peak circuit with that of the carrier circuit, thereby making the operation of the power amplifier circuit 4000 as the Doherty amplifier unstable. What is more, the magnetic field produced in the bump 4620 induces electromotive force in the bumps connected to the same semiconductor substrate as that to which the bump 4620 is connected. For example, electromotive force is induced in a bump (not shown) of a signal converter corresponding to the signal converter 1210 shown in FIG. 1, a bump (not shown) of a divider corresponding to the divider 1100, a bump (not shown) for inputting a harmonic wave signal, and a bump (not shown) for supplying DC power. This makes the output from the peak circuit unstable, thereby making the operation of the power amplifier circuit 4000 as the Doherty amplifier unstable.

In contrast, as shown in FIG. 2, the power amplifier circuit 1000 according to the first embodiment is configured in the following manner. The emitter 1241a is electrically connected to the emitter 1242a via the conductive member 1510. The emitter 1241a is electrically connected to the ground electrode 1700 via the bump 1610, while the emitter 1242a is electrically connected to the ground electrode 1700 via the bump 1620. That is, the bump 1610 is electrically connected in parallel with the bump 1620. With this configuration, the combined inductance of the bumps 1610 and 1620 becomes smaller than the inductance of the bump 4610 of the power amplifier circuit 4000. Hence, the magnetic field produced around the bumps 1610 and 1620 of the output amplifier 1240 of the power amplifier circuit 1000 becomes less intense than that of the bump 4610 of the power amplifier circuit 4000. That is, the power amplifier circuit 1000 is able to reduce the electromotive force induced in the output amplifier 1340 and the driver amplifier 1330 of the peak circuit 1300 caused by the influence of the magnetic field produced in the output amplifier 1240. As a result, the power amplifier circuit 1000 can operate more stably as the Doherty amplifier than the power amplifier circuit 4000.

As illustrated in FIG. 14, in the power amplifier circuit 5000, the emitters 5241a and 5242a are not connected to each other via a conductive member. In the power amplifier circuit 5000, the emitter 5241a is electrically connected to a ground electrode 5700 via a bump 5610, while the emitter 5242a is electrically connected to the ground electrode 5700 via a bump 5620. In the power amplifier circuit 5000, a harmonic wave current flowing through a transistor 5241 and a radio-frequency current flowing through a transistor 5242 do not cancel out each other, and a high radio-frequency current flows through the bumps 5610 and 5620. Hence, the magnitude of the electromotive force induced in a bump 5630 becomes different from that in a bump 5640 in accordance with the distance from the bump 5610 to the bump 5630 and the distance from the bump 5620 to the bump 5640. This fluctuates the operation of the peak circuit, which makes the operation of the power amplifier circuit 5000 unstable.

In contrast, as illustrated in FIG. 2, in the power amplifier circuit 1000 according to the first embodiment, the emitter 1241a is electrically connected to the emitter 1242a via the conductive member 1510. With this configuration, in the power amplifier circuit 1000, a radio-frequency current flowing through the transistor 1241 and that through the transistor 1242 cancel out each other. As a result, a radio-frequency current flowing through the bumps 1610 and 1620 is significantly decreased compared with the radio-frequency current flowing through the bumps 5610 and 5620 of the power amplifier circuit 5000. Additionally, in the power amplifier circuit 1000, the emitter 1341a is electrically connected to the emitter 1342a via the conductive member 1520. With this configuration, in the power amplifier circuit 1000, electromotive force is induced in the bumps 1630 and 1640 due to the magnetic flux passing through between the bumps 1630 and 1640. In the power amplifier circuit 1000, since the bumps 1630 and 1640 are connected to each other via the ground electrode 1700 and the conductive member 1520, the direction of the electromotive force induced in the bump 1630 and that in the bump 1640 become opposite each other. The electromotive force induced in the bump 1630 and that in the bump 1640 thus cancel out each other. As a result, the power amplifier circuit 1000 can operate more stably as the Doherty amplifier than the power amplifier circuit 5000.

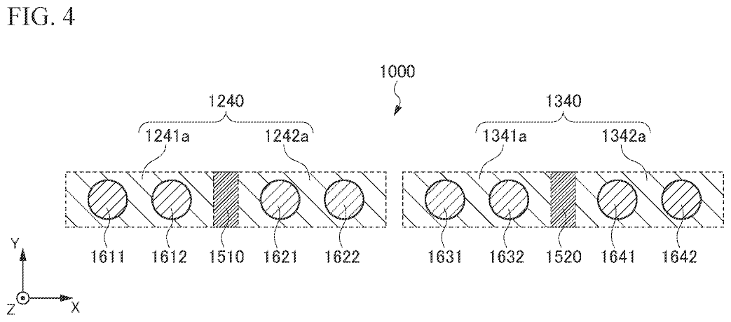

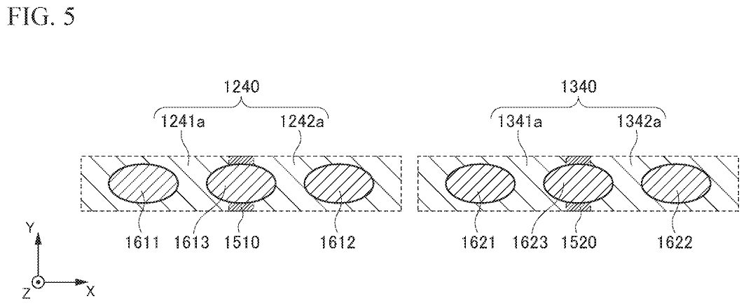

A description will now be given, with reference to FIGS. 4 and 5, of modified examples regarding the connection relationship of the output amplifier 1240 of the carrier circuit 1200 and the output amplifier 1340 of the peak circuit 1300 to the ground electrode 1700. FIGS. 4 and 5 each illustrate an example of the positional relationship between the bumps and the emitters as viewed from above. FIG. 4 illustrates an example of an XY cross section including the emitters 1241a and 1242a of the output amplifier 1240 and the emitters 1341a and 1342a of the output amplifier 1340. FIG. 5 illustrates another example of the XY cross section including the emitters 1241a and 1242a of the output amplifier 1240 and the emitters 1341a and 1342a of the output amplifier 1340. The definitions of the X axis, Y axis, and Z axis in FIGS. 4 and 5 are similar to those of the X axis, Y axis, and Z axis shown in FIGS. 2 and 3.

As described above, as shown in FIG. 2, in the power amplifier circuit 1000, the emitter 1241a of the output amplifier 1240 is electrically connected to the ground electrode 1700 via the bump 1610, while the emitter 1242a of the output amplifier 1240 is electrically connected to the ground electrode 1700 via the bump 1620. However, the positional relationship between the bumps and the emitters is not limited to this configuration. For instance, in the power amplifier circuit 1000, each of the emitters 1241a and 1242a of the output amplifier 1240 may be electrically connected to the ground electrode 1700 via plural bumps electrically connected in parallel with each other, for example.

More specifically, as illustrated in FIG. 4, in the power amplifier circuit 1000, the emitter 1241a of the output amplifier 1240 may be electrically connected to the ground electrode 1700 via bumps 1611 and 1612, for example, while the emitter 1242a may be electrically connected to the ground electrode 1700 via bumps 1621 and 1622, for example. This configuration can further reduce the inductance to a smaller level than when each of the emitters 1241a and 1242a is connected to the ground electrode 1700 via one bump. Increasing the number of bumps electrically connected in parallel with each other in this manner can distribute a stress occurring in the semiconductor substrate 1500, thereby enhancing the physical stability of the power amplifier circuit 1000. In the power amplifier circuit 1000, the output amplifier 1340 may be configured similarly to the output amplifier 1240 or may be configured differently from the output amplifier 1240.

As illustrated in FIG. 5, in the power amplifier circuit 1000, the conductive member 1510 which electrically connects the emitters 1241a and 1242a of the output amplifier 1240 with each other may be electrically connected to the ground electrode 1700 via a bump 1613, for example. This configuration can further reduce the inductance to a smaller level than when each of the emitters 1241a and 1242a is connected to the ground electrode 1700 via one bump. Increasing the number of bumps electrically connected in parallel with each other in this manner can distribute a stress occurring in the semiconductor substrate 1500, thereby enhancing the physical stability of the power amplifier circuit 1000. Additionally, for example, the bumps 1611, 1612, and 1613 may be formed in an oval shape as viewed in the XY cross section. With this configuration, in the power amplifier circuit 1000, the semiconductor substrate 1500 and the ground electrode 1700 can be connected to each other by a large area, thereby improving the heat dissipation characteristics.

### Manufacturing Method for Power Amplifier Circuit 1000 According to First Embodiment

A manufacturing method for the power amplifier circuit 1000 will now be described below with reference to FIG. 2. For the sake of convenience, the manufacturing method for the power amplifier circuit 1000 will be discussed below by referring to a portion of the power amplifier circuit 1000, more specifically, by referring to the output amplifiers 1240 and 1340 as an example. An oxide film is first formed in or on the semiconductor substrate 1500 by sputtering, for example.

A resist is applied onto the oxide film to form patterns corresponding to desired wiring patterns and electrodes. Then, an unnecessary portion of the resist is removed using a developer solution. The portions of the oxide film to form the desired wiring patterns and electrodes (such as the emitters 1241a, 1242a, 1341a, and 1342a) are removed by etching. Then, the remaining resist is stripped, thereby forming a lithographic pattern. Impurities are diffused into the lithographic pattern, thereby forming transistors (such as the transistors 1241, 1242, 1341, and 1342) on the semiconductor substrate 1500. Then, the bumps 1610, 1620, 1630, and 1640 are formed in or on the emitters 1241a, 1242a, 1341a, and 1342a on the semiconductor substrate 1500. Then, the semiconductor substrate 1500 is turned over to face the ground electrode 1700 and is subjected to reflow soldering by heating, thereby connecting the bumps and the ground electrode with each other.

### Power Amplifier Circuit 2000 According to Second Embodiment

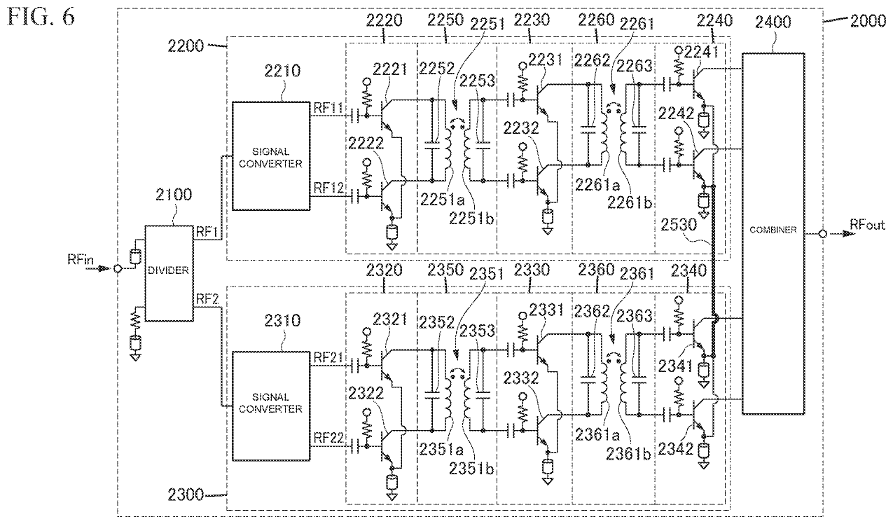

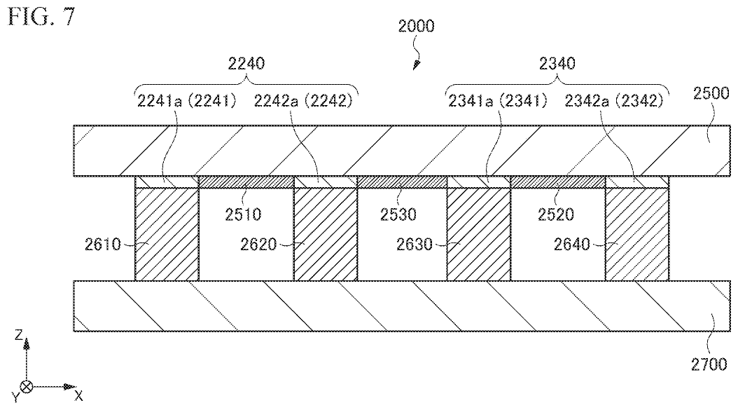

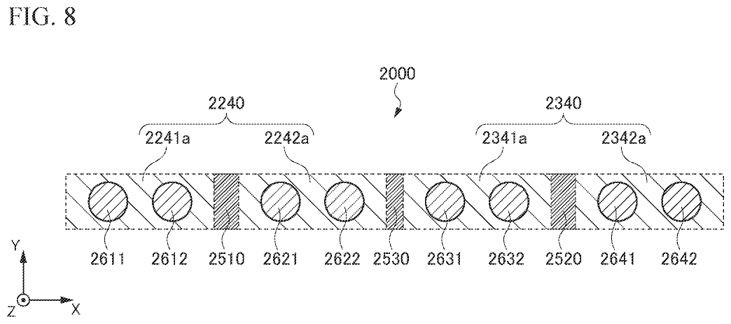

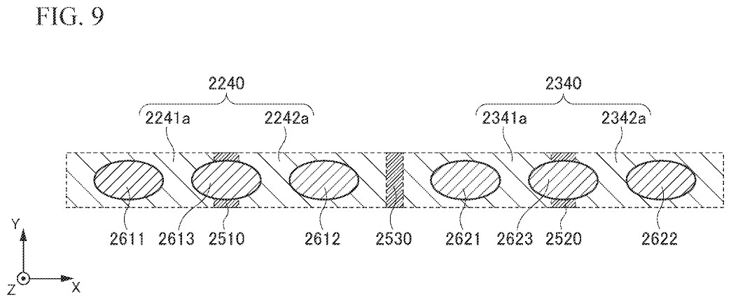

The configuration of a power amplifier circuit 2000 according to a second embodiment will be described below with reference to FIGS. 6 through 9. FIG. 6 is a schematic diagram illustrating an example of the configuration of the power amplifier circuit 2000 according to the second embodiment. FIG. 7 illustrates an example of an XZ cross section including emitters 2241a and 2242a of an output amplifier 2240 and emitters 2341a and 2342a of an output amplifier 2340 according to the second embodiment. FIG. 8 illustrates an example of an XY cross section including the emitters 2241a and 2242a of the output amplifier 2240 and the emitters 2341a and 2342a of the output amplifier 2340 according to the second embodiment. FIG. 9 illustrates another example of the XY cross section including the emitters 2241a and 2242a of the output amplifier 2240 and the emitters 2341a and 2342a of the output amplifier 2340 according to the second embodiment. Hereinafter, for the sake of convenience, an explanation will be given only of portions of the power amplifier circuit 2000 different from the power amplifier circuit 1000 of the first embodiment.

As illustrated in FIGS. 6 and 7, in the power amplifier circuit 2000, for example, the emitter 2242a of the output amplifier 2240 and the emitter 2341a of the output amplifier 2340 are electrically connected to each other via a conductive member 2530. With this configuration, a radio-frequency current, which is caused by an insufficient differential operation of the output amplifier 2240, flows into a ground electrode 2700 via the bumps 2610, 2620, 2630, and 2640. That is, the power amplifier circuit 2000 can further reduce the inductance of the bumps to a smaller level than the power amplifier circuit 1000. This makes a magnetic field produced in the bumps of the output amplifiers 2240 and 2340 smaller than that in the power amplifier circuit 1000. This leads to a decrease in the electromotive force induced in a bump which electrically connects a driver amplifier 2230 or 2330 and the ground electrode, for example. As a result, the power amplifier circuit 2000 can operate stably as the Doherty amplifier. The conductive member 2530 may be an inductor or a resistor element, for example. This can secure the isolation between the output amplifiers 2240 and 2340, thereby stabilizing the operation of the power amplifier circuit 2000 as the Doherty amplifier.

As illustrated in FIG. 8, in the power amplifier circuit 2000, the emitter 2241a of the output amplifier 2240 may be electrically connected to the ground electrode 2700 via bumps 2611 and 2612, for example, while the emitter 2242a may be electrically connected to the ground electrode 2700 via bumps 2621 and 2622, for example. This configuration can reduce the inductance of the bumps while securing the isolation between the output amplifiers 2240 and 2340. Increasing the number of bumps electrically connected in parallel with each other can distribute a stress occurring in a semiconductor substrate 2500, thereby enhancing the physical stability of the power amplifier circuit 2000.

As illustrated in FIG. 9, in the power amplifier circuit 2000, a conductive member 2510, which electrically connects the emitters 2241a and 2242a of the output amplifier 2240 with each other, may be electrically connected to the ground electrode 2700 via a bump 2613, for example.

This configuration can reduce the inductance of the bumps while securing the isolation between the output amplifiers 2240 and 2340. Additionally, for example, the bumps 2611, 2612, and 2613 may be formed in an oval shape as viewed in the XY cross section. This can distribute a stress occurring in the semiconductor substrate 2500, thereby enhancing the physical stability of the power amplifier circuit 2000.

### Power Amplifier Circuit 3000 According to Another Embodiment

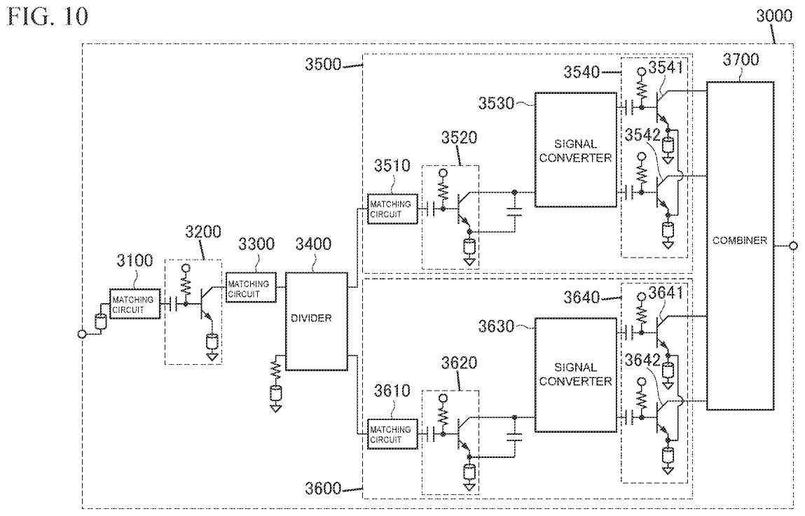

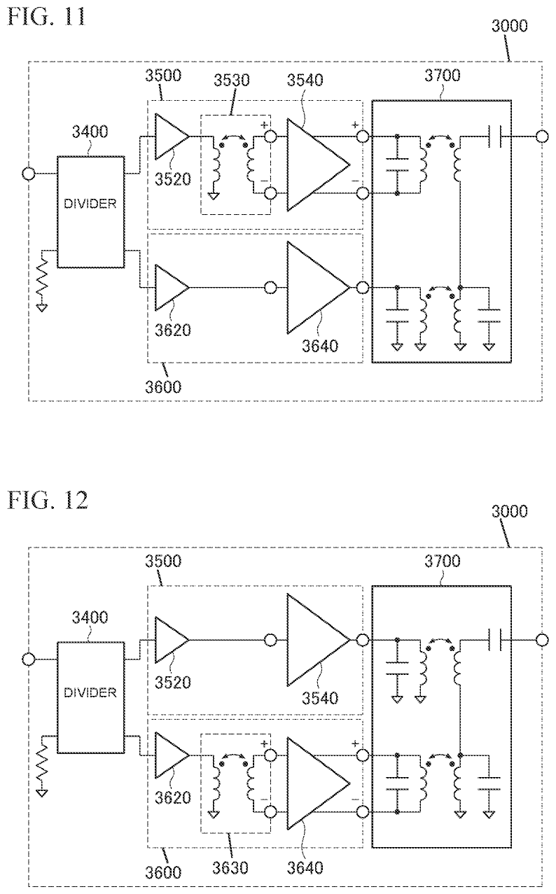

The configuration of a power amplifier circuit 3000 according to another embodiment will be described below with reference to FIGS. 10 through 12. FIG. 10 is a schematic diagram illustrating an example of the configuration of the power amplifier circuit 3000 according to another embodiment. FIGS. 11 and 12 are schematic diagrams illustrating other examples of the configuration of the power amplifier circuit 3000 according to this embodiment. Hereinafter, for the sake of convenience, an explanation will be given only of portions of the power amplifier circuit 3000 different from the power amplifier circuit 1000 of the first embodiment. As described above, in the power amplifier circuit 1000 according to the first embodiment, for example, each of the buffer amplifiers 1220 and 1320, driver amplifiers 1230 and 1330, and output amplifiers 1240 and 1340 forms a differential amplifier circuit. However, the power amplifier circuit 1000 is not restricted to this configuration. In the power amplifier circuit 1000, for example, at least one of the output amplifier 1240 of the carrier circuit 1200 and the output amplifier 1340 of the peak circuit 1300 may form a differential amplifier circuit.

As one specific example, the configuration of the power amplifier circuit 3000 according to this embodiment will be discussed below with reference to FIGS. 10 and 11. As illustrated in FIG. 10, the power amplifier circuit 3000 may include a matching circuit 3100, a buffer amplifier 3200, a matching circuit 3300, a divider 3400, a carrier circuit 3500, a peak circuit 3600, and a combiner 3700, for example. The carrier circuit 3500 may include a matching circuit 3510, a single-ended driver amplifier 3520, a signal converter 3530, and an output amplifier 3540, which is a differential amplifier circuit. The peak circuit 3600 may include a matching circuit 3610, a single-ended driver amplifier 3620, a signal converter 3630, and an output amplifier 3640, which is a differential amplifier circuit. As illustrated in FIG. 11, a modified example of the power amplifier circuit 3000 may include a divider 3400, a carrier circuit 3500, and a peak circuit 3600. The carrier circuit 3500 may include a driver amplifier 3520, a signal converter 3530, and an output amplifier 3540, which is a differential amplifier circuit. The peak circuit 3600 may include a driver amplifier 3620 and an output amplifier 3640, neither of which is a differential amplifier circuit. In the power amplifier circuit 3000 shown in FIGS. 10 and 11, in the output amplifier 3540 of the carrier circuit 3500, the emitter of a transistor 3541 and the emitter of a transistor 3542 are electrically connected to each other via a conductive member, and each of the emitters is electrically connected to a ground electrode via at least one bump. With this configuration, in the power amplifier circuit 3000, it is possible to reduce the electromotive force induced in the output amplifier 3640 and the driver amplifier 3620 of the peak circuit 3600 caused by the influence of a magnetic field produced in the output amplifier 3540. The power amplifier circuit 3000 can thus operate stably as the Doherty amplifier.

As another modified example, as illustrated in FIG. 12, the power amplifier circuit 3000 may include a divider 3400, a carrier circuit 3500, and a peak circuit 3600. The carrier circuit 3500 may include a single-ended driver amplifier 3520 and a single-ended output amplifier 3540. The peak circuit 3600 may include a single-ended driver amplifier 3620 and an output amplifier 3640, which is a differential amplifier circuit. In the power amplifier circuit 3000 shown in FIG. 12, in the output amplifier 3640 of the peak circuit 3600, the emitter of a transistor 3641 (see FIG. 10) and the emitter of a transistor 3642 (see FIG. 10) are electrically connected to each other via a conductive member, and each of the emitters is electrically connected to a ground electrode via at least one bump. With this configuration, in the power amplifier circuit 3000, it is possible to reduce the electromotive force induced in the driver amplifier 3520 of the carrier circuit 3500 caused by the influence of a magnetic field produced in the output amplifier 3640. The power amplifier circuit 3000 can thus operate stably as the Doherty amplifier.

### CONCLUSIONS

A power amplifier circuit 1000 includes an output amplifier 1240 (first carrier amplifier) and an output amplifier 1340 (first peak amplifier). The output amplifier 1240 (first carrier amplifier) includes a differential amplifier circuit having a transistor 1241 (first transistor) and a transistor 1242 (second transistor). The output amplifier 1340 (first peak amplifier) is formed in or on a semiconductor substrate 1500, which is the same semiconductor substrate 1500 in or on which the output amplifier 1240 (first carrier amplifier) is formed. The emitter or the source of the transistor 1241 (first transistor) is electrically connected to the emitter or the source of the transistor 1242 (second transistor). The emitter or the source of the transistor 1241 (first transistor) is electrically connected to a ground electrode 1700 via a bump 1610 (first bump). The emitter or the source of the transistor 1242 (second transistor) is electrically connected to the ground electrode 1700 via a bump 1620 (second bump), which is different from the bump 1610 (first bump). With this configuration, the power amplifier circuit 1000 can reduce the inductance of the bumps (bumps 1610 and 1620 in this example) to a smaller level than the power amplifier circuit 4000. This can reduce the electromotive force induced in the output amplifier 1340 of the peak circuit 1300 caused by the influence of a magnetic field produced in the output amplifier 1240. As a result, the power amplifier circuit 1000 can operate stably as the Doherty amplifier.

The output amplifier 1340 (first peak amplifier) of the power amplifier circuit 1000 includes a differential amplifier circuit having a transistor 1341 (third transistor) and a transistor 1342 (fourth transistor). The emitter or the source of the transistor 1341 (third transistor) is electrically connected to the emitter or the source of the transistor 1342 (fourth transistor). With this configuration, the power amplifier circuit 1000 can reduce a radio-frequency current flowing through the bumps of the peak circuit 1300 to a smaller level than the power amplifier circuit 5000, thereby stabilizing the operation of the output amplifier 1340 of the peak circuit 1300. As a result, the power amplifier circuit 1000 can operate stably as the Doherty amplifier.

The emitter or the source of the transistor 1341 (third transistor) of the power amplifier circuit 1000 is electrically connected to the ground electrode 1700 via a bump 1630 (third bump). The emitter or the source of the transistor 1342 (fourth transistor) is electrically connected to the ground electrode 1700 via a bump 1640 (fourth bump). With this configuration, the power amplifier circuit 1000 can reduce the inductance of the bumps (bumps 1630 and 1640 in this example) to a smaller level than the power amplifier circuit 4000. This can reduce the electromotive force induced in the output amplifier 1340 of the peak circuit 1300 caused by the influence of a magnetic field produced in the output amplifier 1240 of the carrier circuit 1200. As a result, the power amplifier circuit 1000 can operate stably as the Doherty amplifier.

In a power amplifier circuit 2000, the emitter or the source of a transistor 2241 (first transistor) or the emitter or the source of a transistor 2242 (second transistor) in an output amplifier 2240 (first carrier amplifier) is electrically connected to the emitter or the source of a transistor 2341 (third transistor) of an output amplifier 2340 (first peak amplifier) via a conductive member 2530. With this configuration, the power amplifier circuit 2000 can reduce the inductance of the bumps to a smaller level than the power amplifier circuit 1000. This can reduce the electromotive force induced in the bumps which electrically connect the ground electrode and a driver amplifier 2230 of a carrier circuit 2200 or a driver amplifier 2330 of a peak circuit 2300. As a result, the power amplifier circuit 2000 can operate stably as the Doherty amplifier.

The bump 1610 (first bump) of the power amplifier circuit 1000 includes plural bumps (bumps 1611 and 1612 shown in FIG. 4 or bumps 1611 and 1613 shown in FIG. 5) electrically connected in parallel with each other, as those illustrated in FIGS. 4 and 5. This configuration can further reduce the inductance to a smaller level than when an emitter 1241a is connected to the ground electrode 1700 via one bump. Increasing the number of bumps electrically connected in parallel with each other in this manner can distribute a stress occurring in the semiconductor substrate 1500, thereby enhancing the physical stability of the power amplifier circuit 1000.

The bump 1620 (second bump) of the power amplifier circuit 1000 includes plural bumps (bumps 1621 and 1622 shown in FIG. 4 or bumps 1612 and 1613 shown in FIG. 5) electrically connected in parallel with each other, as those illustrated in FIGS. 4 and 5. This configuration can further reduce the inductance to a smaller level than when an emitter 1242a is connected to the ground electrode 1700 via one bump. Increasing the number of bumps electrically connected in parallel with each other in this manner can distribute a stress occurring in the semiconductor substrate 1500, thereby enhancing the physical stability of the power amplifier circuit 1000.

The bump 1630 (third bump) of the power amplifier circuit 1000 includes plural bumps (bumps 1631 and 1632 shown in FIG. 4 or bumps 1621 and 1623 shown in FIG. 5) electrically connected in parallel with each other, as those illustrated in FIGS. 4 and 5. This configuration can further reduce the inductance to a smaller level than when an emitter 1341a is connected to the ground electrode 1700 via one bump. Increasing the number of bumps electrically connected in parallel with each other in this manner can distribute a stress occurring in the semiconductor substrate 1500, thereby enhancing the physical stability of the power amplifier circuit 1000.

The bump 1640 (fourth bump) of the power amplifier circuit 1000 includes plural bumps (bumps 1641 and 1642 shown in FIG. 4 or bumps 1622 and 1623 shown in FIG. 5) electrically connected in parallel with each other, as those illustrated in FIGS. 4 and 5. This configuration can further reduce the inductance to a smaller level than when an emitter 1342a is connected to the ground electrode 1700 via one bump. Increasing the number of bumps electrically connected in parallel with each other in this manner can distribute a stress occurring in the semiconductor substrate 1500, thereby enhancing the physical stability of the power amplifier circuit 1000.

The conductive member 2530 of the power amplifier circuit 2000 is an inductor or a resistor element. This can secure the isolation between the output amplifiers 2240 and 2340, thereby stabilizing the operation of the power amplifier circuit 2000 as the Doherty amplifier.

The power amplifier circuit 1000 further includes a driver amplifier 1230 (second carrier amplifier) and a driver amplifier 1330 (second peak amplifier). The driver amplifier 1230 (second carrier amplifier) is connected in series with the output amplifier 1240 (first carrier amplifier) at the input side of the output amplifier 1240 (first carrier amplifier). The driver amplifier 1330 (second peak amplifier) is connected in series with the output amplifier 1340 (first peak amplifier) at the input side of the output amplifier 1340 (first peak amplifier). With this configuration, the power amplifier circuit 1000 can reduce the electromotive force induced in the output amplifier 1340 and the driver amplifier 1330 of the peak circuit 1300 caused by the influence of a magnetic field produced in the output amplifier 1240. As a result, the power amplifier circuit 1000 can operate stably as the Doherty amplifier.

In the power amplifier circuit 1000, the collector or the drain of the output amplifier 1240 (first carrier amplifier) and the collector or the drain of the output amplifier 1340 (first peak amplifier) are electrically connected to a combiner. With this structure of the power amplifier circuit 1000, the inductance of the bumps between the ground electrode 1700 and the output amplifier 1240 through which a higher radio-frequency current flows than in the other elements of the carrier circuit 1200 can be decreased, thereby reducing the electromotive force induced in the peak circuit 1300. As a result, the power amplifier circuit 1000 can operate stably as the Doherty amplifier.

The driver amplifier 1330 (second peak amplifier) of the power amplifier circuit 1000 is formed in or on a semiconductor substrate 1500, which is the same semiconductor substrate 1500 in or on which the output amplifier 1240 (first carrier amplifier) is formed. With this configuration, the power amplifier circuit 1000 can reduce the electromotive force induced in the bumps which electrically connect the ground electrode and the driver amplifier 1230 of the carrier circuit 1200 or the driver amplifier 1330 of the peak circuit 1300. As a result, the power amplifier circuit 1000 can operate stably as the Doherty amplifier.

A power amplifier circuit 3000 includes an output amplifier 3540 (third carrier amplifier), a driver amplifier 3520 (fourth carrier amplifier), an output amplifier 3640 (third peak amplifier), and a driver amplifier 3620 (fourth peak amplifier). The driver amplifier 3520 (fourth carrier amplifier) is connected in series with the output amplifier 3540 (third carrier amplifier) at the input side of the output amplifier 3540 (third carrier amplifier). The output amplifier 3640 (third peak amplifier) includes a differential amplifier circuit having a transistor (transistor 1341 in FIG. 1, for example) (sixth transistor) and a transistor (transistor 1342 in FIG. 1, for example) (seventh transistor), which is different from the transistor (transistor 1341 in FIG. 1, for example) (sixth transistor). The driver amplifier 3620 (fourth peak amplifier) is connected in series with the output amplifier 3640 (third peak amplifier) at the input side of the output amplifier 3640 (third peak amplifier). The emitter or the source of the transistor (transistor 1341 in FIG. 1, for example) (sixth transistor) is electrically connected to a ground electrode (ground electrode 1700 in FIG. 2, for example) via a bump (bump 1630 in FIG. 2, for example) (fifth bump). The emitter or the source of the transistor (transistor 1342 in FIG. 1, for example) (seventh transistor) is electrically connected to the ground electrode (ground electrode 1700 in FIG. 2, for example) via a bump (bump 1640 in FIG. 2, for example) (sixth bump), which is different from the bump (bump 1630 in FIG. 2, for example) (fifth bump). With this configuration, the power amplifier circuit 3000 can reduce the electromotive force induced in the driver amplifier 3520 of the carrier circuit 3500 caused by the influence of a magnetic field produced in the output amplifier 3640. As a result, the power amplifier circuit 3000 can operate stably as the Doherty amplifier.

A power amplifier circuit 1000 includes an output amplifier 1240 (first carrier amplifier) and an output amplifier 1340 (first peak amplifier). The output amplifier 1240 (first carrier amplifier) includes a differential amplifier circuit having a transistor 1241 (first transistor) and a transistor 1242 (second transistor). The output amplifier 1340 (first peak amplifier) is formed in or on a semiconductor substrate 1500, which is the same semiconductor substrate 1500 in or on which the output amplifier 1240 (first carrier amplifier) is formed. The emitter or the source of the transistor 1241 (first transistor) is electrically connected to the emitter or the source of the transistor 1242 (second transistor). The emitter or the source of the transistor 1241 (first transistor) is electrically connected to a ground electrode 1700 using a via 1650 (first via). The emitter or the source of the transistor 1242 (second transistor) is electrically connected to the ground electrode 1700 using a via 1660 (second via), which is different from the via 1650 (first via). With this configuration, the power amplifier circuit 1000 can reduce the inductance of the via (via 1650 in FIG. 3 in this example) to a smaller level than the power amplifier circuit 4000. This can reduce the electromotive force induced in the output amplifier 1340 of the peak circuit 1300 caused by the influence of a magnetic field produced in the output amplifier 1240. As a result, the power amplifier circuit 1000 can operate stably as the Doherty amplifier.

The above-described embodiments are provided for facilitating the understanding of the disclosure, but are not intended to be exhaustive or to limit the disclosure to the precise forms disclosed. Modifications or improvements may be made without departing from the spirit and scope of the disclosure, and equivalents of the disclosure are also encompassed in the disclosure. That is, suitable design changes made to the embodiments by those skilled in the art are also encompassed in the disclosure within the spirit and scope of the disclosure. For example, the elements and the positions thereof in the embodiments are not restricted to those described in the embodiments and may be changed if necessary.

1000, 2000, 3000 power amplifier circuit, 1240, 1340 output amplifier, 1230, 1330 driver amplifier, 1500 semiconductor substrate, 1700 ground electrode

1. A power amplifier circuit comprising:
a first carrier amplifier comprising a carrier differential amplifier circuit that comprises a first transistor and a second transistor, the first carrier amplifier being in or on a semiconductor substrate; and
a first peak amplifier that is in or on the semiconductor substrate,
wherein an emitter or a source of the first transistor is electrically connected to an emitter or a source of the second transistor,
wherein the emitter or the source of the first transistor is electrically connected to a ground electrode by a first bump, and
wherein the emitter or the source of the second transistor is electrically connected to the ground electrode by a second bump, the second bump being different from the first bump.

2. The power amplifier circuit according to claim 1,
wherein the first peak amplifier comprises a peak differential amplifier circuit comprising a third transistor and a fourth transistor, and
wherein an emitter or a source of the third transistor is electrically connected to an emitter or a source of the fourth transistor.

3. The power amplifier circuit according to claim 2,
wherein the emitter or the source of the third transistor is electrically connected to the ground electrode by a third bump, and
wherein the emitter or the source of the fourth transistor is electrically connected to the ground electrode by a fourth bump, the fourth bump being different from the third bump.

4. The power amplifier circuit according to claim 2, wherein the emitter or the source of the first transistor or the emitter or the source of the second transistor is electrically connected to the emitter or the source of the third transistor by a conductor.

5. The power amplifier circuit according to claim 1, wherein the first bump comprises a plurality of bumps electrically connected in parallel with each other.

6. The power amplifier circuit according to claim 1, wherein the second bump comprises a plurality of bumps electrically connected in parallel with each other.

7. The power amplifier circuit according to claim 3, wherein the third bump comprises a plurality of bumps electrically connected in parallel with each other.

8. The power amplifier circuit according to claim 3, wherein the fourth bump comprises a plurality of bumps electrically connected in parallel with each other.

9. The power amplifier circuit according to claim 4, wherein the conductor is an inductor or a resistor.

10. The power amplifier circuit according to claim 1, further comprising:
a second carrier amplifier that is connected in series with the first carrier amplifier at an input side of the first carrier amplifier; and
a second peak amplifier that is connected in series with the first peak amplifier at an input side of the first peak amplifier.

11. The power amplifier circuit according to claim 10, wherein a collector or a drain of the first carrier amplifier and a collector or a drain of the first peak amplifier are electrically connected to a combiner.

12. The power amplifier circuit according to claim 10, wherein the second peak amplifier is in or on the semiconductor substrate.

13. A power amplifier circuit comprising:
a third carrier amplifier;
a fourth carrier amplifier that is connected in series with the third carrier amplifier at an input side of the third carrier amplifier;
a third peak amplifier comprising a peak differential amplifier circuit that comprises a sixth transistor and a seventh transistor; and
a fourth peak amplifier that is connected in series with the third peak amplifier at an input side of the third peak amplifier,
wherein an emitter or a source of the sixth transistor is electrically connected to a ground electrode by a fifth bump, and
wherein an emitter or a source of the seventh transistor is electrically connected to the ground electrode by a sixth bump, the sixth bump being different from the fifth bump.

14. A power amplifier circuit comprising:
a first carrier amplifier comprising a differential amplifier circuit that comprises a first transistor and a second transistor, the first carrier amplifier being in or on a semiconductor substrate; and
a first peak amplifier that is in or on the semiconductor substrate,
wherein an emitter or a source of the first transistor is electrically connected to an emitter or a source of the second transistor,
wherein the emitter or the source of the first transistor is electrically connected to a ground electrode by a first via, and
wherein the emitter or the source of the second transistor is electrically connected to the ground electrode by a second via, the second via being different from the first via.
